(19) United States
(12) Patent Application Publication
(10) Pub. No.: US 2011/0254092 A1
(43) Pub. Date: Oct. 20, 2011

(54) ETSOI CMOS ARCHITECTURE WITH DUAL BACKSIDE STRESSORS

(75) Inventors: Bin Yang, Mahwah, NJ (US); Michael Hargrove, Clinton Corners, NY (US)

(73) Assignee: GLOBALFOUNDRIES Inc., Grand Cayman (KY)

(21) Appl. No.: 12/759,969

(22) Filed: Apr. 14, 2010

(51) Int. Cl. H01L 27/092; H01L 21/31

(52) U.S. Cl. 257/351; 438/761; 257/E27.062; 257/E21.24

(57) ABSTRACT

A semiconductor is formed on an ETSOI layer, the thin Si layer of an ETSOI substrate, with enhanced channel stress. Embodiments include semiconductor devices having dual stress liners on the back surface of the ETSOI layer. An embodiment includes forming an ETSOI substrate comprising an extra thin layer of Si on a backside substrate with an insulating layer, e.g., a BOX, there between, forming a semiconductor device on the Si surface, removing the backside substrate, as by CMP and the insulting layer, as by wet etching, and forming a stress liner on the backside of the remaining Si layer opposite the semiconductor device. The use of stress liners on the backside of the ETSOI layer enhances channel stress without modifying ETSOI semiconductor process flow.

### TECHNICAL FIELD

The present disclosure relates to semiconductor devices based on silicon-on-insulator (SOI), particularly extremely thin silicon-on-insulator (ETSOI), and FinFET semiconductor devices with enhanced channel stress. The present disclosure is particularly applicable to 22 nanometer (nm) node devices and beyond.

### BACKGROUND

Complementary metal-oxide-semiconductor (CMOS) scaling to smaller and smaller pitches, such as 22 nm node and beyond, causes undesirable short channel effects, such as off-state leakage current. To reduce the off-state leakage current, and thereby improve CMOS short channel behavior, while maintaining the 0.7 times scaling factor between technology nodes, a new device architecture is needed. CMOS devices based on ETSOI, comprising an extremely thin silicon (Si) layer, as at a thickness less than about 8 nm, e.g., between about 6 nm and about 8 nm, on an Si substrate with an insulating layer, e.g., a buried oxide layer (BOX), there between, and FinFET are promising candidates for future generations of CMOS due to their fundamentally superior short channel control characteristics.

In addition, with CMOS scaling, the smaller pitch between gates significantly reduces stressor volume, and, therefore, stressor benefit. The pitch scaling effect is true for all known stressors, such as tensile stress liners for nMOS, compressive stress liners for pMOS, embedded silicon germanium (eSiGe) pMOS stressor, and embedded silicon carbide (eSi:C) nMOS stressors. An approach to improve the stressor benefit without gate pitch scaling effects and without altering CMOS fabrication processes on the front end, is to apply stress to the backside of the channel. However, known techniques for applying stress to the backside of the channel require a thick Si body, which is incompatible with ETSOI's extremely thin body of Si. In addition, existing techniques for applying stress to the back also require two epitaxial growths, reversely-embedded Si:C under the pMOS channel and reversely-embedded SiGe under the nMOS channel, which is incompatible with the non-planar FinFET architecture.

A need therefore exists for improved methodology enabling enhanced channel stress and channel mobility of a CMOS device from the backside of the channel, and for the resulting device.

### SUMMARY

An aspect of the present disclosure is an ETSOI semiconductor device including a stress liner on the backside of the Si layer.

Another aspect of the present disclosure is a method of fabricating an SOI semiconductor device including a stress liner on the backside of the Si layer.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method comprising: forming an SOI substrate comprising a layer of Si on a backside substrate with an insulating layer, e.g., a BOX, there between; forming a semiconductor device on the Si surface of the ETSOI substrate; removing the backside substrate and the insulating layer; and forming a stress liner on the backside of the remaining Si opposite the semiconductor.

Aspects of the present disclosure include forming the semiconductor device by forming an n-MOS transistor, and forming the stress liner by forming a compressively stressed layer. Another aspect includes forming the semiconductor device by forming a p-MOS transistor, and forming the stress liner by forming a tensilely stressed layer. Further aspects include forming the compressively stressed layer of silicon nitride at a thickness of about 300 Å to about 600 Å. Additional aspects include forming the tensilely stressed layer of silicon nitride at a thickness of about 300 Å to about 600 Å. Other aspects include forming a CMOS semiconductor device comprising an n-MOS transistor and p-MOS transistor; forming a compressively stressed layer on the backside opposite the n-MOS transistor; and forming a tensilely stressed layer on the backside opposite the p-MOS transistor. Further aspects include forming the tensilely stressed layer on the backside opposite both the p-MOS transistor and the n-MOS transistor; removing the tensilely stressed layer from the backside opposite the n-MOS transistor, leaving the tensilely stressed layer on the backside opposite the p-MOS transistor; and forming the compressively stressed layer on the backside opposite the p-MOS transistor. Another aspect includes the Si layer having a thickness of about 6 nm to about 8 nm. Other aspects include the backside substrate comprising Si, and the method comprising: removing the backside Si substrate by chemical mechanical polishing (CMP); and removing the BOX by selectively wet etching.

Another aspect of the present disclosure is a device comprising: an ETSOI layer of Si having a top surface and a backside surface opposite the top surface; a semiconductor device formed on the top surface of the Si layer; and a stress liner on the backside surface of the Si layer.

Aspects include the semiconductor device comprising an n-MOS transistor; and the stress liner comprising a compressively stressed layer opposite the n-MOS transistor. Further aspects include the compressively stressed layer comprising silicon nitride at a thickness of about 300 Å to about 600 Å. Another aspect includes the semiconductor device comprising a p-MOS device; and the stress liner comprising a tensilely stressed layer opposite the p-MOS transistor. Other aspects include the tensilely stressed layer comprising silicon nitride at a thickness of about 300 Å to about 600 Å. Additional aspects include the semiconductor device comprising a CMOS semiconductor device comprising an n-MOS transistor and a p-MOS transistor; and the stress liner comprising a compressively stressed layer on the backside opposite the n-MOS transistor and a tensilely stressed layer on the backside opposite the p-MOS transistor. Further aspects include the Si layer has a thickness of about 6 nm to about 8 nm.

Another aspect of the present disclosure is a method comprising: forming an ETSOI substrate comprising a layer of Si on a backside substrate with an insulating layer (BOX) there between; forming an n-MOS transistor and a p-MOS transistor on a top surface of the Si layer opposite the backside substrate; forming a first tensile stress liner on the n-MOS transistor and a first compressive stress liner on the p-MOS transistor; forming dielectric layers and metal interconnect layers on the stress liners; bonding a handling substrate to the dielectric and metal interconnect layers; removing the backside substrate and BOX; forming a second tensile stress liner on the backside of the Si layer under the p-MOS transistor; and forming a second compressive stress liner on the backside of the Si layer under the n-MOS transistor.

Further aspects include forming the second tensile liner on the backside of the Si layer under both the n-MOS transistor and the p-MOS transistor; forming a photoresist on the second tensile liner under the p-MOS transistor; removing the second tensile liner under the n-MOS transistor; removing the photoresist; and forming the second compressive liner on the backside of the Si layer under the n-MOS transistor. Additional aspects include forming the second compressive liner on the backside of the Si layer under both the n-MOS transistor and the p-MOS transistor; forming a photoresist on the second compressive liner under the n-MOS transistor; removing the second compressive liner under the p-MOS transistor; removing the photoresist; and forming the second tensile liner on the backside of the Si layer under the p-MOS transistor. Other aspects include forming the second tensile liner and second compressive liner of silicon nitride at a thickness of about 300 Å to about 600 Å.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1 through 6 schematically illustrate sequential steps of a method in accordance with an exemplary embodiment.

FIG. 7 schematically illustrates a CMOS device in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments.

The present disclosure addresses and solves the off-state leakage current and channel stress problems attendant upon small gate pitches with CMOS scaling. In accordance with embodiments of the present disclosure, after a CMOS device is formed on the Si layer of an SOI substrate, the insulating layer, e.g., BOX, and substrate underlying the Si layer are selectively removed and dual stress liners are formed on the backside of the Si layer. Consequently, channel stress and channel mobility are enhanced without requiring modification of the SOI device fabrication processes on the front side of the substrate. Further, when ETSOI substrates are employed, off-state leakage current may be reduced.

Methodology in accordance with embodiments of the present disclosure includes forming an SOI substrate comprising a layer of Si on a backside substrate with an insulating layer there between, forming a semiconductor device on the Si surface of the SOI substrate, removing the backside substrate and insulating layer, and forming a stress liner on the backside of the remaining Si opposite the semiconductor.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

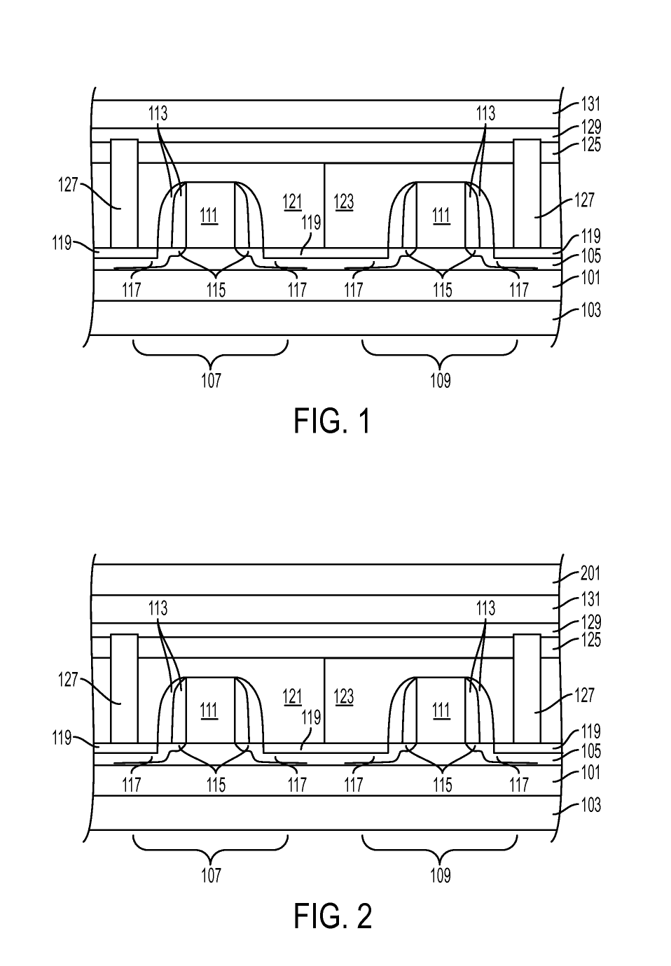

One of the benefits of the present disclosure is that channel stressors may be added without altering conventional processing of SOI, and particularly CMOS devices based on ETSOI. Accordingly, a process in accordance with an exemplary embodiment begins with conventional front-end-of line (FEOL) processing for an SOI CMOS device. Adverting to FIG. 1, BOX layer 101 is formed on Si substrate 103, and Si layer 105 is formed on BOX layer 101, to form an SOI substrate. Si layer 105 may have a thickness between about 6 nm and about 8 nm, thereby forming an ETSOI substrate. Shallow trench isolation regions and well implants (not shown) may be formed in Si layer 105. nFET 107 and pFET 109 are each formed with gate stack 111, spacers 113, halo/extension regions 115, and source/drain regions 117, followed by rapid thermal anneal (RTA) and/or laser scribe anneal (LSA), to densify the spacers, to diffuse source/drain dopants, and to form silicide 119.

Gate stack 111 may include, for example, a gate dielectric layer, such as a silicon oxide, and a gate electrode formed of amorphous Si or polysilicon. Alternatively, gate stack 111 may include a high-k dielectric, such as a hafnium based oxide, a hafnium based oxynitride, or a hafnium-silicon oxynitride, and a metal gate electrode formed of titanium nitride, tantalum nitride, or aluminum nitride. Spacers 113 may, for example, be formed of silicon nitride or silicon oxide, and silicide 119 may, for example, be nickel, cobalt, or nickel-platinum silicide.

The process continues with conventional middle-of-line (MOL) techniques for forming tensile liner 121 over nFET 107, compressive liner 123 over pFET 109, dielectric layer 125, and contact vias 127 through dielectric layer 125 and stress liners 121 and 123. A first metal contact layer 129 and other back-end-of-line (BEOL) dielectric and metal inter-connect layers 131 are then formed to complete a conventional ETSOI CMOS.

Compressive liner 121, e.g., a compressively stressed silicon nitride, may be formed, for example, by depositing silicon nitride over both the nFET 107 and pFET 109, applying a photoresist or hard mask over the pFET, and removing the compressively stressed silicon nitride film from the nFET transistor. The photoresist may then be removed from the pFET, and tensile liner 123 may be formed. For example, a tensilely stressed silicon nitride film may be deposited over both the pFET and nFET. A photoresist or hard mask, may then applied over the nFET, and the tensilely stressed silicon nitride film may be selectively removed from the pFET. Then, the photoresist may be removed leaving compressive liner 121 and tensile liner 123.

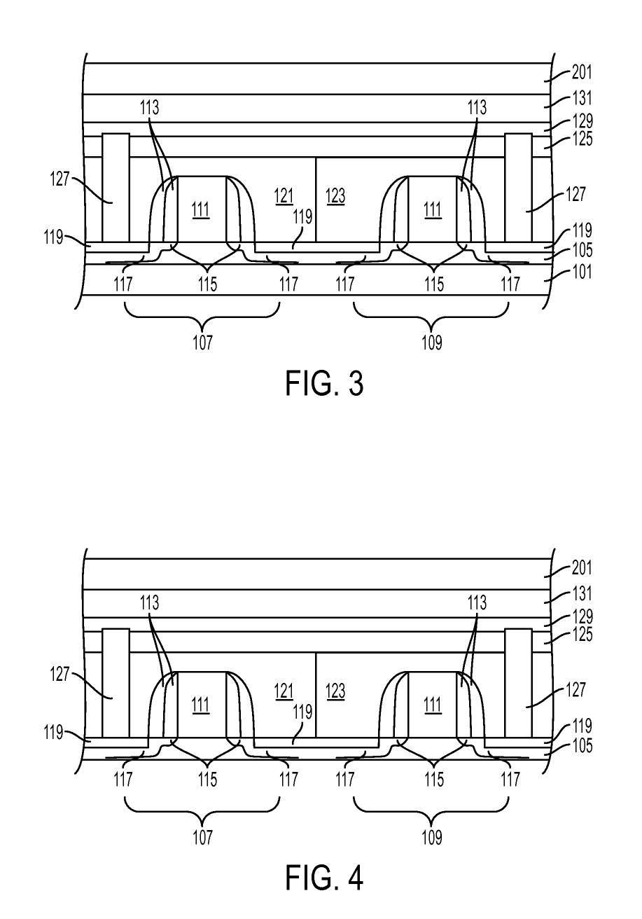

As illustrated in FIG. 2, subsequent to BEOL process completion, chemical mechanical polishing (CMP) is performed on the top surface of the device, and a handling substrate 201, e.g., a Si wafer, is bonded thereto. Next, as illustrated in FIG. 3, Si substrate 103 is removed, for example, by performing CMP on the bottom surface of the device, stopping on BOX layer 101. Then, BOX layer 101 is removed, e.g., by employing a wet etchant such as hydrofluoric acid (HF), and selectively stopping on Si layer 105. The result of removing BOX layer 101 is illustrated in FIG. 4.

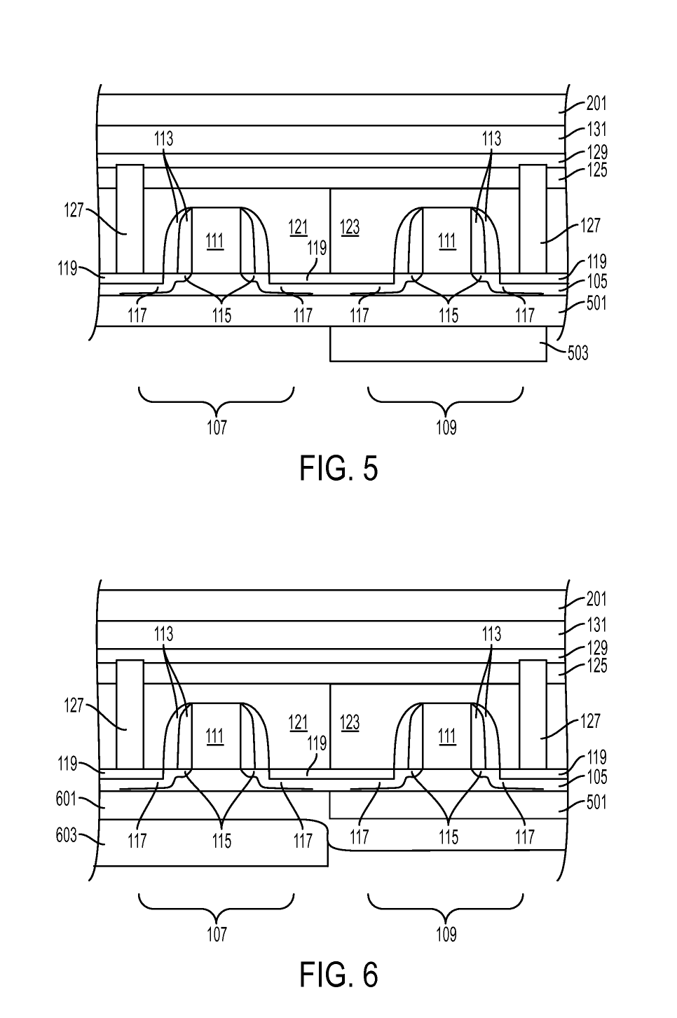

Adverting to FIG. 5, tensile liner 501, e.g., a tensilely stressed silicon nitride layer, is deposited on the back surface of Si layer 105, under both nFET 107 and pFET 109. Tensile liner 501 may be deposited to a thickness of about 300 Å to about 600 Å. A photoresist and/or hard mask 503 is formed on tensile liner 501, under pFET 109. The portion of tensile liner 501 that is exposed, i.e., the portion under nFET 107 is removed by wet etching, for example by employing hydrofluoric acid (HF) or diluted hydrofluoric acid (DHF). Since wet etching normally causes some lateral etch, the mask should be designed to compensate for the occurrence of lateral etch. After tensile liner 501 is removed from under nFET 107, photoresist 503 is removed.

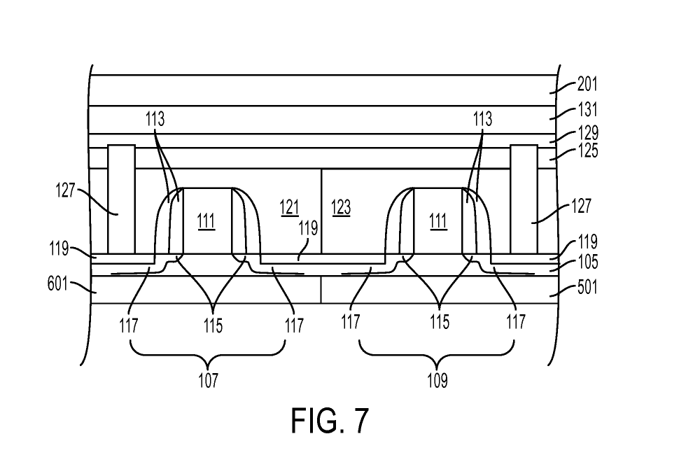

As illustrated in FIG. 6, compressive liner 601, e.g., a compressively stressed silicon nitride layer, is deposited on the back surface of Si layer 105 and tensile liner 501, under nFET 107 and pFET 109, respectively. Compressive liner 601 may be deposited to a thickness of about 300 Å to about 600 Å. Since the stress is function of the thickness of the stress liners, the thickness of both liners should be selected for the desired stress. A photoresist and/or hard mask 603 is formed on compressive liner 601, under nFET 107. The portion of compressive liner 601 that is exposed, i.e., the portion under pFET 109 is removed, as by wet etching. Then, photoresist 603 is removed. The resulting CMOS is illustrated in FIG. 7. Alternatively, compressive liner 601 may be formed first and then tensile liner 501.

The embodiments of the present disclosure can achieve several technical effects, including enhanced channel stress and channel mobility not limited by gate pitch and with no modification to SOI device fabrication processes on the front side of the substrate. The present disclosure enjoys industrial applicability in any of various types of highly integrated semiconductor devices, particularly 22 nm node devices and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming an SOI substrate comprising a layer of silicon (Si) on a backside substrate with an insulating layer there between;
forming a semiconductor device on the Si surface of the SOI substrate;
removing the backside substrate and the insulating layer; and
forming a stress liner on the backside of the remaining Si opposite the semiconductor.

2. The method according to claim 1, comprising forming the semiconductor device by forming an n-MOS transistor, and forming the stress liner by forming a compressively stressed layer.

3. The method according to claim 1, comprising forming the semiconductor device by forming a p-MOS transistor, and forming the stress liner by forming a tensilely stressed layer.

4. The method according to claim 2, comprising forming the compressively stressed layer of silicon nitride at a thickness of about 300 Å to about 600 Å.

5. The method according to claim 3, comprising forming the tensilely stressed layer of silicon nitride at a thickness of about 300 Å to about 600 Å.

6. The method according to claim 1, comprising:
forming a CMOS semiconductor device comprising an n-MOS transistor and p-MOS transistor;
forming a compressively stressed layer on the backside opposite the n-MOS transistor; and
forming a tensilely stressed layer on the backside opposite the p-MOS transistor.

7. The method according to claim 6, comprising:
forming the tensilely stressed layer on the backside opposite both the p-MOS transistor and the n-MOS transistor;
removing the tensilely stressed layer from the backside opposite the n-MOS transistor, leaving the tensilely stressed layer on the backside opposite the p-MOS transistor; and
forming the compressively stressed layer on the backside opposite the p-MOS transistor.

8. The method according to claim 1, wherein the Si layer has a thickness of about 6 nm to about 8 nm.

9. The method according to claim 1, wherein the backside substrate comprises Si, the method comprising:
removing the backside Si substrate by chemical mechanical polishing (CMP); and
removing the insulating layer by selectively wet etching.

10. A device comprising:
an ETSOI layer of silicon (Si) having a top surface and a backside surface opposite the top surface;
a semiconductor device formed on the top surface of the Si layer; and
a stress liner on the backside surface of the Si layer.

11. The device according to claim 10, wherein:
the semiconductor device comprises an n-MOS transistor; and
the stress liner comprises a compressively stressed layer opposite the n-MOS transistor.

12. The device according to claim 11, wherein the compressively stressed layer comprises silicon nitride at a thickness of about 300 Å to about 600 Å.

13. The device according to claim 10, wherein:
the semiconductor device comprises a p-MOS transistor; and
the stress liner comprises a tensilely stressed layer.

14. The device according to claim 13, wherein the tensilely stressed layer comprises silicon nitride at a thickness of about 300 Å to about 600 Å.

15. The device according to claim 10, wherein:
the semiconductor device comprises a CMOS semiconductor device comprising an n-MOS transistor and a p-MOS transistor; and
the stress liner comprises a compressively stressed layer on the backside opposite the n-MOS transistor and a tensilely stressed layer on the backside opposite the p-MOS transistor.

16. The semiconductor device according to claim 1, wherein the Si layer has a thickness of about 6 nm to about 8 nm.

17. A method of fabricating a semiconductor device comprising:
forming an ETSOI substrate comprising a layer of silicon (Si) on a backside substrate with an insulating layer (BOX) there between;
forming an n-MOS transistor and a p-MOS transistor on a top surface of the Si layer opposite the backside substrate;
forming a first tensile stress liner on the n-MOS transistor and a first compressive stress liner on the p-MOS transistor;
forming dielectric layers and metal interconnect layers on the stress liners;
bonding a handling substrate to the dielectric and metal interconnect layers;
removing the backside substrate and BOX;
forming a second tensile stress liner on the backside of the Si layer under the p-MOS transistor; and
forming a second compressive stress liner on the backside of the Si layer under the n-MOS transistor.

18. The method according to claim 17, comprising:
forming the second tensile liner on the backside of the Si layer under both the n-MOS transistor and the p-MOS transistor;
forming a photoresist on the second tensile liner under the p-MOS transistor;
removing the second tensile liner under the n-MOS transistor;
removing the photoresist; and
forming the second compressive liner on the backside of the Si layer under the n-MOS transistor.

19. The method according to claim 17, comprising:
forming the second compressive liner on the backside of the Si layer under both the n-MOS transistor and the p-MOS transistor;
forming a photoresist on the second compressive liner under the n-MOS transistor;
removing the second compressive liner under the p-MOS transistor;
removing the photoresist; and
forming the second tensile liner on the backside of the Si layer under the p-MOS transistor.

20. The method according to claim 17, comprising forming the second tensile liner and second compressive liner of silicon nitride at a thickness of about 300 Å to about 600 Å.
